(19) United States
(12) Patent Application Publication
(10) Pub. No.: US 2024/0411057 A1
(43) Pub. Date: Dec. 12, 2024

(54) PROCESS FOR MANUFACTURING A THREE-DIMENSIONAL STRUCTURE IN BENDING

(71) Applicant: COMMISSARIAT A L'ENERGIE ATOMIQUE ET AUX ENERGIES ALTERNATIVES, Paris (FR)

(72) Inventors: Raphaël FEOUGIER, Grenoble Cedex 09 (FR); Nicolas POSSEME, Grenoble Cedex 09 (FR); Raluca TIRON, Grenoble Cedex 09 (FR); Maxime ARGOUD, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/632,562

(22) Filed: Apr. 11, 2024

(30) Foreign Application Priority Data
Apr. 12, 2023 (FR) 23 03637

(51) Int. Cl. G02B 3/00; B81C 1/00

(52) U.S. Cl. CPC G02B 3/0012; B81C 1/00023; B81C 1/00555

(57) ABSTRACT

A method for manufacturing a three-dimensional structure comprising supplying a stack comprising, stacked in a vertical direction, a support substrate, a sacrificial layer, a layer of interest having a sidewall and a tensor layer having a sidewall, the tensor layer having a residual stress. The method also comprises removing a removal portion of the sacrificial layer, while retaining a remaining portion of the sacrificial layer underlying the layer of interest. The removal portion is located in line with a lateral portion of the layer of interest extending from the entire sidewall of the layer of interest. The residual stress of the tensor layer is configured to cause bending of the layer of interest during the step of removing the removal portion.

### TECHNICAL FIELD

The present invention relates to the field of three-dimensional (3D) microstructures, more precisely microstructures having controlled deformation. It finds a particularly advantageous application in the field of microlenses.

### PRIOR ART

There are several techniques for manufacturing 3D microstructures with controlled deformation, particularly for the manufacture of microlenses. Microlenses are generally made by optical lithography followed by thermal creep, as developed by Popovic, Z. D., Sprague, R. A., and Connell, G. A. N., in the publication Technique for monolithic fabrication of microlens arrays, Applied Optics, 27(7): 1281 (1988). These techniques can pose difficulties in terms of reproducibility and predictability of the shape obtained after creep. Other techniques exist for obtaining microlens arrays, in particular grayscale lithography, which is increasingly being studied for the production of 3D structures. Grayscale lithography often involves numerous lithography steps, which results in high budgets. Another commonly used route is 3D pattern printing. This technique uses a mould structured into micro-bowls obtained by optical lithography and/or etching. These patterns are then printed in a resin, thus forming microlenses. Making the mould can be tricky when the dimensions to be obtained are small.

In a field far from that of the production of microlenses, it was noticed that the microdiscs used in photonics as two-dimensional whispering-gallery-mode resonators could deform when they were released from the substrate under the effect of stress relaxation, and take a chip shape (see in particular Li Y. and al, Three-Dimensional Anisotropic Microlaser from GaN-Based Self-Bent-Up Microdisk, ACS Photonics 2018, 5, 11, 4259-4264, 2018, one of the figures of which is reproduced in FIG. 1). However, the shape of the microdisc after deformation depends entirely on its own stresses and cannot be controlled.

An objective of the present invention is therefore to propose a method for deforming microstructures, particularly microlenses, allowing to control the final shape of the structure in a reproducible manner and with a limited budget.

Moreover, the method for deforming a microdisc under the effect of stress relaxation following its release from the substrate as described in the prior art only allows its deformation in a single direction of bending, this direction of bending being induced by the stresses prevailing in the microdisc. Another objective of the invention is to propose a common solution to a tensile deformation and a compressive deformation.

### SUMMARY

To achieve this objective, according to one embodiment, provision is made of a method for manufacturing a three-dimensional structure comprising the following steps:
a. supplying a stack comprising at least, stacked in a direction called vertical direction:
   i. a support substrate,
   ii. a sacrificial layer,
   iii. a layer of interest delimited in all directions of a plane perpendicular to the vertical direction, called the horizontal plane, by a sidewall,
   iv. a tensor layer delimited in all directions of the horizontal plane by a sidewall, the tensor layer having a residual stress σ₁₀₀,
b. removing a portion of the sacrificial layer, called the removal portion, selectively from the layer of interest and the tensor layer, the removal portion forming a closed contour in projection in the horizontal plane, the removal portion being entirely located in line with a lateral portion of the layer of interest extending from the entire sidewall of the layer of interest, the removal of the removal portion being carried out so as to retain a portion of the sacrificial layer, called remaining portion, located in line with the layer of interest and the sacrificial layer.

The residual stress σ₁₀₀ of the tensor layer is configured to cause bending of the layer of interest during the step of removing the removal portion. Advantageously, the residual stress σ₁₀₀ is configured to cause the bending of the entire layer of interest in a single direction of bending during the step of removing the removal portion. This single direction of bending can either correspond to a movement of the entire layer of interest towards the support substrate, or correspond to a movement away from the entire layer of interest towards the support substrate.

In this method, removing the removal portion of the sacrificial layer allows the partial mechanical release of the layer of interest and the tensor layer. The presence of the tensor layer and its mechanical properties allow to stress the layer of interest into a given shape during release. The features of the tensor layer and in particular its residual stress can be configured so as to force the layer of interest into a desired shape. It is therefore possible, thanks to the use of the tensor layer, to very precisely control the shape of the structure obtained at the end of the method.

As will be presented further, both the direction and the amplitude of the deformation of the layer of interest induced by the method according to the invention can be precisely defined and predicted by numerical simulations, which allows to further facilitate deformation control.

Thus, the invention allows to obtain three-dimensional structures, particularly microlenses, with good control of the final shape, in a reproducible manner and while requiring a limited budget.

Another aspect of the invention relates to a method for manufacturing a three-dimensional structure having a symmetry of revolution in the vertical direction. The method comprises the following steps:
a, supplying a stack comprising, stacked in a direction called vertical direction:
   i. a support substrate,
   ii. a sacrificial layer,
   iii. a layer of interest delimited in all directions of a plane perpendicular to the vertical direction, called the horizontal plane, by a sidewall having a symmetry of revolution in the vertical direction,
   iv. a tensor layer delimited in all directions of the horizontal plane by a sidewall having a symmetry of revolution in the vertical direction, the tensor layer having a residual stress σ₁₀₀
b. removing a portion of the sacrificial layer, called the removal portion, selectively from the layer of interest and the tensor layer, the removal portion forming a closed contour in projection in the horizontal plane, the removal portion being located in line with a lateral portion of the layer of interest extending from the entire sidewall of the layer of interest, the removal of the removal portion being carried out so as to retain a portion of the sacrificial layer, called remaining portion, located in line with the layer of interest and the sacrificial layer.

The residual stress σ₁₀₀ of the tensor layer is configured to cause bending of the layer of interest during the step of removing the removal portion.

### BRIEF DESCRIPTION OF THE FIGURES

The purposes, objects, as well as the features and advantages of the invention will emerge better from the detailed description of an embodiment of the latter which is illustrated by the following accompanying drawings wherein:

FIG. 1, taken from the prior art, illustrates a layer having undergone deformation following a relaxation of its stresses.

FIGS. 2A to 2M show a first embodiment of the method according to the invention.

FIG. 2A illustrates the provision of an initial stack comprising a support substrate, a sacrificial layer and a layer of interest.

FIG. 2B illustrates the deposition of a tensor layer on the layer of interest.

FIG. 2C illustrates the deposition of a masking layer on the tensor layer.

FIG. 2D illustrates the structuring of the masking layer according to a chosen pattern,

FIG. 2E illustrates the transfer of the pattern onto the tensor layer through the masking layer.

FIG. 2F illustrates the transfer of the pattern onto the layer of interest through the masking layer.

FIG. 2G illustrates the removal of the masking layer.

FIGS. 2H to 2J illustrate the progressive removal of a removal portion of the sacrificial layer while leaving a remaining portion in place.

FIG. 2K illustrates the bending of the layer of interest and the tensor layer after being released thanks to the removal step.

FIG. 2L illustrates the removal of the tensor layer.

FIG. 2M illustrates a substrate underlying a plurality of 3D structures formed by the method according to the invention.

FIG. 2N is a bottom view of the remaining portion and the layer of interest in the case where the latter have a circular shape.

FIG. 2O is a bottom view of the remaining portion and the layer of interest in the case where the latter have an elliptical shape.

FIG. 22 is a sectional view of the stack before and after deformation.

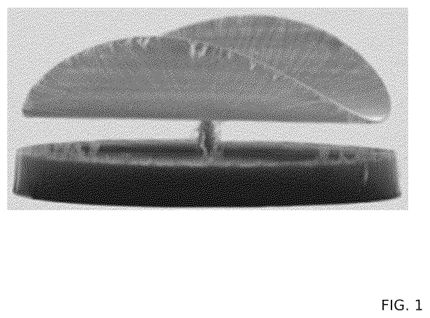

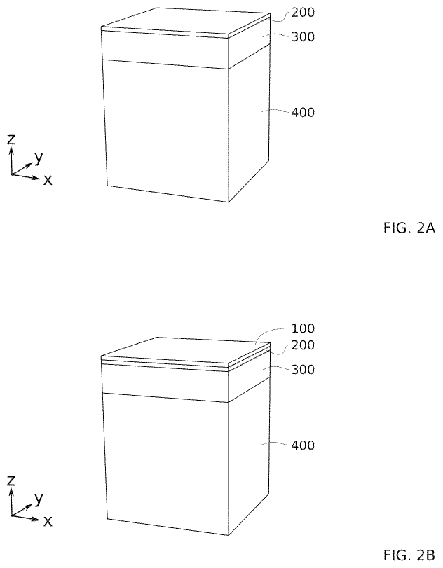

FIGS. 3A to 3O represent a second embodiment of the method according to the invention. FIG. 3A illustrates the provision of an initial stack comprising a support substrate, a sacrificial layer and a layer of interest.

FIG. 3B illustrates the nanostructuring of the layer of interest.

FIG. 3C illustrates the deposition of a planarisation layer on the layer of interest.

FIG. 3D illustrates the deposition of a tensor layer on the planarisation layer.

FIG. 3E illustrates the deposition of a masking layer on the tensor layer.

FIG. 3F illustrates the structuring of the masking layer according to a chosen pattern.

FIG. 3G illustrates the transfer of the pattern onto the tensor layer through the masking layer.

FIG. 3H illustrates the transfer of the pattern onto the planarisation layer and onto the layer of interest through the masking layer.

FIG. 3I illustrates the removal of the masking layer.

FIGS. 3J to 3L illustrate the progressive removal of a removal portion of the sacrificial layer while leaving a remaining portion in place.

FIG. 3M illustrates the bending of the layer of interest and the tensor layer after being released thanks to the removal step.

FIG. 3N illustrates the removal of the tensor layer.

FIG. 3O illustrates the removal of the planarisation layer,

FIGS. 4A to 4L represent a third embodiment of the method according to the invention. FIG. 4A illustrates the provision of an initial stack comprising a support substrate, a sacrificial layer and a layer of interest.

FIG. 4B illustrates the deposition of a tensor layer on the layer of interest.

FIG. 4C illustrates the deposition of a secondary layer of interest on the tensor layer.

FIG. 4D illustrates the nanostructuring of the secondary layer of interest.

FIG. 4E illustrates the deposition of a masking layer on the secondary layer of interest.

FIG. 4F illustrates the structuring of the masking layer according to a chosen pattern.

FIG. 4G illustrates the transfer of the pattern onto the secondary layer of interest, the tensor layer and the layer of interest through the masking layer.

FIG. 4H illustrates the removal of the masking layer.

FIGS. 41 to 4K illustrate the progressive removal of a removal portion of the sacrificial layer while leaving a remaining portion in place.

FIG. 4L illustrates the bending of the layer of interest, the tensor layer and the secondary layer of interest after being released thanks to the removal step.

FIG. 5 shows the profile of the layer of interest after removal of the sacrificial layer for different diameters of the pad.

FIG. 6A shows the profile of the layer of interest as the removal portion of the sacrificial layer is removed, for a layer of interest and a tensor layer having a diameter of 15 μm.

FIG. 6B is a scanning electron microscopy (SEM) image of the same assembly as in FIG. 6A, after complete removal of the removal portion of the sacrificial layer.

FIG. 7A shows the profile of the layer of interest as the removal portion of the sacrificial layer is removed, for a layer of interest and a tensor layer having a diameter of 20 μm.

FIGS. 7B to 7D are scanning electron microscopy (SEM) images of the same assembly as in FIG. 7A, after complete removal of the removal portion of the sacrificial layer.

FIG. 8A illustrates the experimental (solid lines) and theoretical (dashed lines) results of the profile of the layer of interest obtained for different diameters of residual pads.

FIG. 8B illustrates the maximum deflection obtained as a function of the diameter of the residual pad by numerical simulations (square points) and experimentally (triangular points).

The drawings are given as examples and do not limit the invention. They constitute schematic representations of principle intended to facilitate the understanding of the invention and are not necessarily on the scale of practical applications. In particular, the dimensions are not representative of reality.

### DETAILED DESCRIPTION

Before beginning a detailed review of embodiments of the invention, the following are set out as optional features which may possibly be used in combination or alternatively:

According to one example, the removal of the removal portion is carried out so as to expose the lateral portion of the layer of interest.

According to an advantageous embodiment, the sidewall of the layer of interest and the sidewall of the tensor layer each have a substantially elliptical or substantially circular shape in projection in the horizontal plane.

According to an advantageous embodiment, the remaining portion has a sidewall having a substantially elliptical or substantially circular shape in projection in the horizontal plane.

According to a preferred example, the sidewall of the layer of interest, the sidewall of the tensor layer and the sidewall of the remaining portion each have a substantially circular shape in projection in the horizontal plane. The layer of interest has a diameter D200 in the horizontal plane and the remaining portion has a diameter D360 in the horizontal plane. After removing the removal portion, the layer of interest has an arrow f₂₀₀, with f₂₀₀≥0.05*(D₂₀₀−D₃₆₀), preferably f₂₀₀≥0.10*(D₂₀₀−D₃₆₀).

According to an advantageous example, the layer of interest has a diameter D₂₀₀; in the horizontal plane and the remaining portion has a diameter D₃₆₀ in the horizontal plane. After removing the removal portion, the ratio D₂₀₀/D₃₆₀ is greater than 2, preferably greater than 3.

According to a preferred example, the sidewall of the layer of interest, the sidewall of the tensor layer and the sidewall of the remaining portion each have a substantially elliptical shape in projection in the horizontal plane. The layer of interest has a minor axis D_{200,y} in the horizontal plane and the remaining portion has a minor axis D_{360,y} in the horizontal plane. After removing the removal portion, the layer of interest has, in section along a plane perpendicular to the horizontal plane and containing the minor axis of the layer of interest, an arrow f₂₀₀, with f₂₀₀≥0.05*(D_{200,y}−D_{360,y}), preferably f₂₀₀≥0.10*(D_{200,y}−D_{360,y}).

Preferably, the arrow f₂₀₀ of the layer of interest after removing the removal portion is greater than 100 nm, preferably greater than 200 nm and even according to certain embodiments greater than 500 nm. This can be the case regardless of the shape of the layer of interest, in particular circular or elliptical.

Preferably, at least during the removal step, the sidewall of the tensor layer is in the extension of the sidewall of the layer of interest in the vertical direction.

Advantageously, the method further comprises, after the step of removing the removal portion, a step of removing the tensor layer.

According to one example, the bending of the layer of interest brings its sidewall closer to the substrate.

Advantageously, the method is configured so that the bending of the layer of interest causes contact of the layer of interest with the support substrate.

Preferably, the method comprises bonding at least part of the layer of interest with the support substrate.

Preferably, the bonding of at least part of the layer of interest with the support substrate is caused at least in part, and preferably only, by contacting the layer of interest with the support substrate.

According to one example, the bending of the layer of interest moves its sidewall away from the substrate.

According to one example, the layer of interest has a thickness e₂₀₀ in the vertical direction with e₂₀₀≤300 nm. This allows to limit the residual stress necessary in the tensor layer to allow deformation of the layer of interest. This also helps reduce the stiffness of the layer of interest.

According to one example, which |σ₁₀₀|>500 MPa and preferably |σ₁₀₀|>1000 MPa.

This ensures significant deformation of the layer of interest According to a preferred example, before the removal step, the layer of interest has a residual stress σ₂₀₀ with |σ₂₀₀|≤100 MPa. This allows to limit the residual stress necessary in the tensor layer to allow deformation of the layer of interest. This allows in particular to be able to achieve deformations of the layer of interest of several nanometres or even micrometres.

According to one example, the sacrificial layer is based on at least one of an oxide such as SiO₂ or SiON or a nitride such as SiN. The sacrificial layer can also be an anti-reflective layer based on silicon (designated by the acronym SiARC, “Silicon containing Anti-Reflective Coating”). The sacrificial layer can advantageously be removed by etching with HF or H₃PO₄ In the case of a sacrificial layer based on a nitride such as SiN, in order to facilitate HF removal, the nitride in question could advantageously be deposited at low temperature, for example at a temperature below 500° C., or even be oxygenated.

According to one example, the tensor layer is based on at least one of TiN, AlN, SiN and Si₃N₄. Advantageously, the tensor layer is based on a metal.

According to one example, the layer of interest is based on at least one of Si and SiGe. Advantageously, the layer of interest is based on a conductive material.

According to one example, the layer of interest is based on an amorphous material. This allows to overcome variations in intrinsic physical properties related to crystal directions. Therefore, this allows to homogenize the deformation.

According to a preferred embodiment, the layer of interest, after the step of removing the removal portion of the sacrificial layer, forms a lens.

According to a preferred embodiment, the stack comprises a plurality of layers of interest distinct from each other and contained in the same plane parallel to the horizontal plane before the step of removing the removal portion of the sacrificial layer.

According to one example, the stack comprises a plurality of layers of interest distinct from each other and surmounting a single substrate.

Preferably, each layer of interest forms a lens.

According to one embodiment, the method comprises, prior to the step of removing the removal portion of the sacrificial layer, a step of structuring the at least one layer of interest.

Preferably, the step of structuring the at least one layer of interest is carried out before the step of providing the stack.

According to one embodiment, the stack further comprises a secondary layer of interest above the tensor layer, the removal of the removal portion is also carried out selectively at the secondary layer of interest, and the method further comprises, prior to the step of removing the removal portion, a step of structuring the secondary layer of interest, According to one example, the structuring step comprises the implementation of at least one technique among optical lithography, self-assembly of block copolymers and nanoimprinting.

The residual stresses prevailing in certain materials and which are mentioned in this application are induced by the different steps of deposition and transformation of these materials. The residual stresses in a layer can be of mechanical origin and in particular be generated during its formation. They are then often related to the methods and conditions of deposition. Residual stresses can also be of thermal origin. Then, they depend on the thermal variations undergone by the layer, its thermal properties as well as those of the substrate on which it rests. This thermal component can therefore change during the manufacturing steps.

Various methods can be used to measure the residual stress prevailing in a layer. X-ray diffraction (XRD) is typically used. By adapting the wavelength of the X-rays emitted as a function of the material studied and by studying the angular distribution of the X-rays diffracted by the sample, it is possible to draw a curve relating the inter-reticular distance d to the measured angle and to the properties χ of the materials (curve typically of the type d=sin²(χ)). The curve thus obtained allows to determine the state and level of stress of the sample in the measured direction, Residual stress can also be measured by laser interferometry. In this case, the radius of curvature of the substrate supporting the layer for which it is sought to know the level of residual stress is measured before and after deposition of the layer (or before and after a step of treating the layer). The mechanical stress values are calculated directly using the Stoney formula, knowing the thickness of the layer and the substrate, their Young moduli and their respective Poisson ratios. Moreover, the level of residual stress can be measured by Raman spectroscopy, a technique based on variations in the Raman frequencies of optical phonons. This technique has the advantages of being non-destructive, very sensitive and having sub-nanometric spatial resolution.

It is specified that, in the context of the present invention, the terms “on”, “surmounts”, “covers”, “underlying”, “vis-à-vis” and their equivalents do not necessarily mean “in contact with”. For example, the deposition, transfer, bonding, assembly or application of a first layer on a second layer does not necessarily mean that the two layers are in direct contact with each other, but means that the first layer at least partially covers the second layer by being either directly in contact therewith or by being separated therefrom by at least one other layer or at least one other element.

A layer can also be composed of several sub-layers of the same material or of different materials.

A substrate, a layer, a device, “based” on a material M, means a substrate, a layer, a device comprising this material M only or this material M and possibly other materials, for example elements alloy, impurities or doping elements. Thus a material based on a Ill-N material can comprise a Ill-N material with added dopants.

“Selective etching with respect to” or “etching having selectivity with respect to” means an etching configured to remove a material A or a layer A with respect to a material B or a layer B, and having an etching speed of material A greater than the etching speed of material B. The selectivity is the ratio between the etching speed of material A to the etching speed of material B. The selectivity between A and B is denoted SA:B.

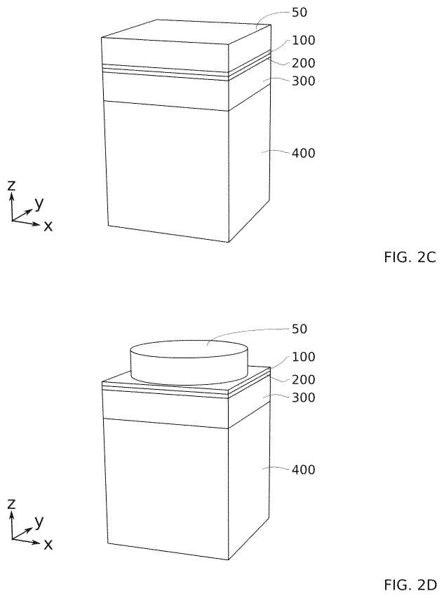

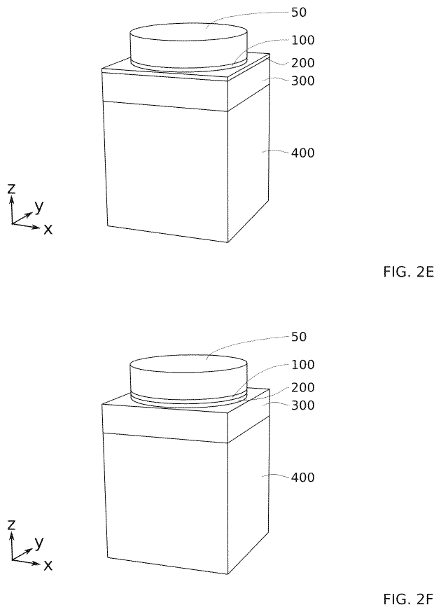

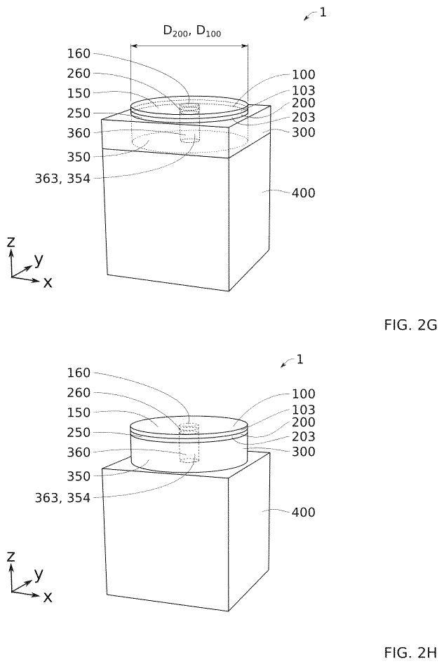

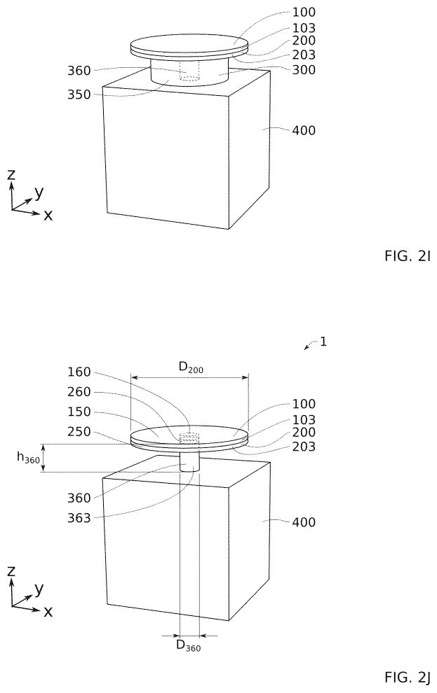

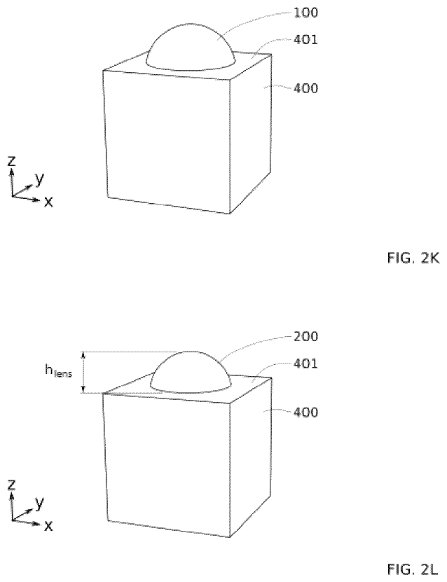

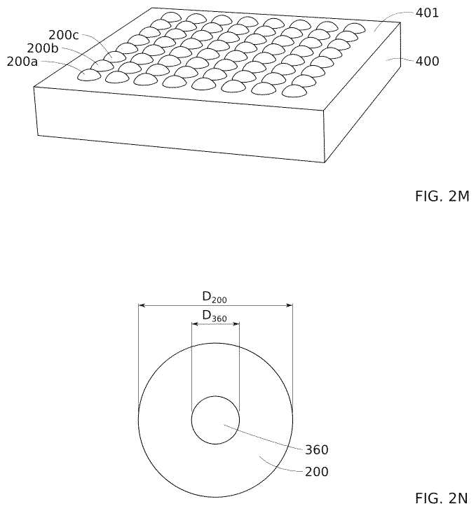

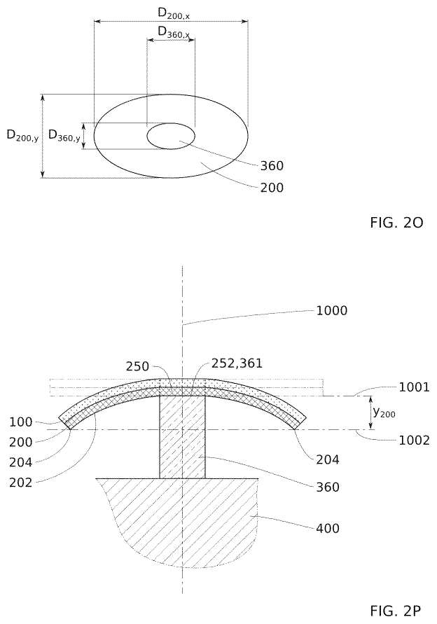

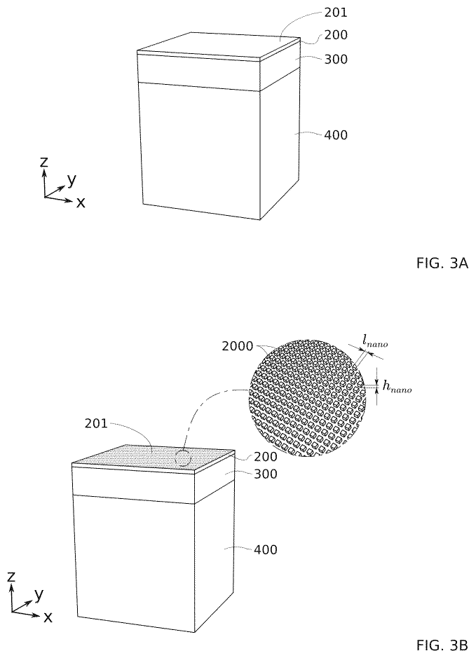

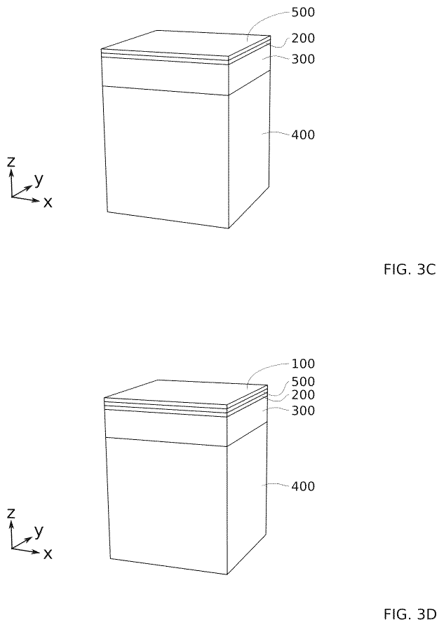

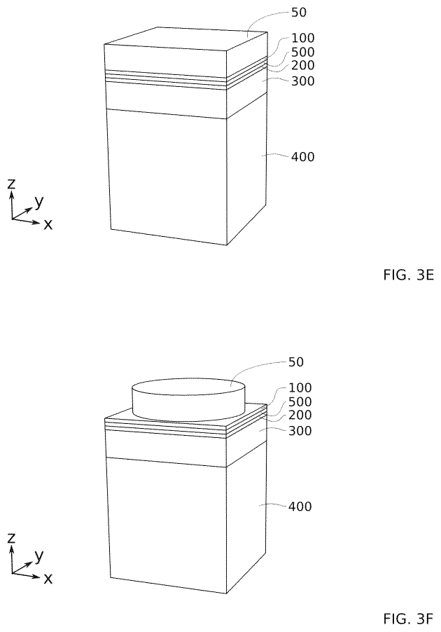

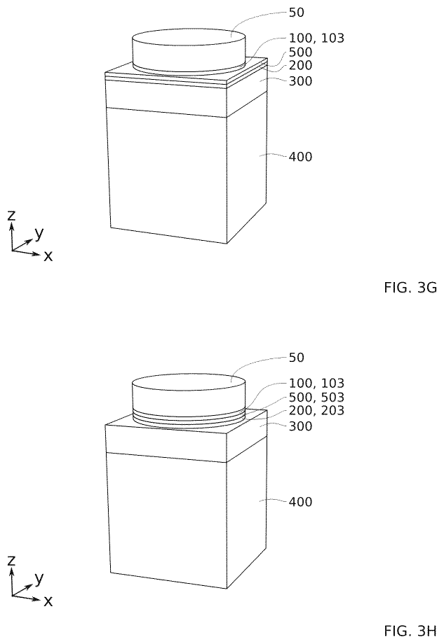

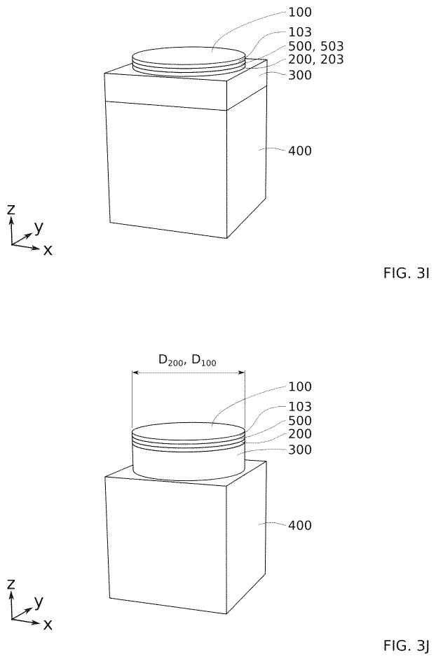

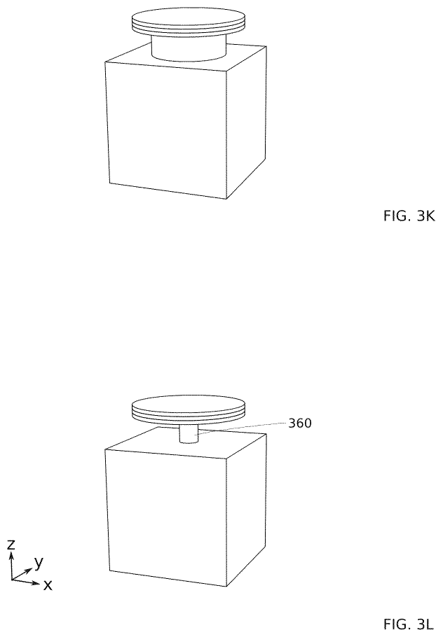

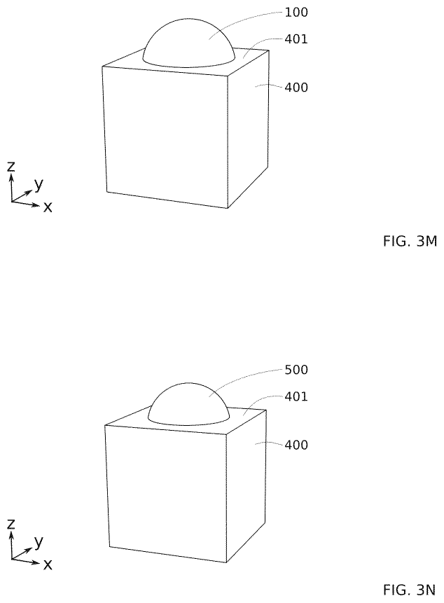

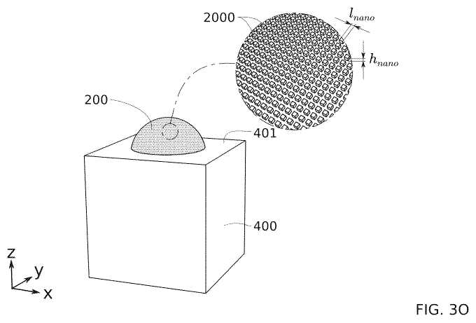

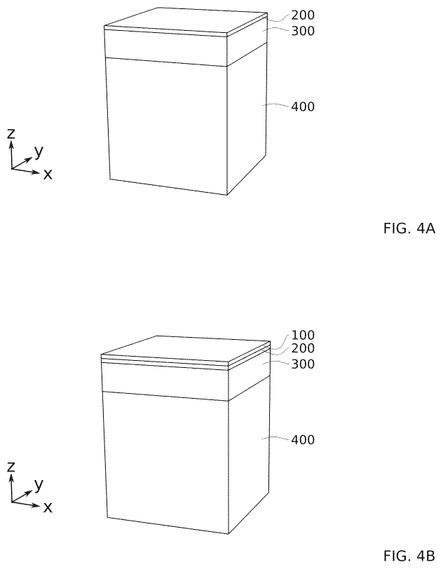

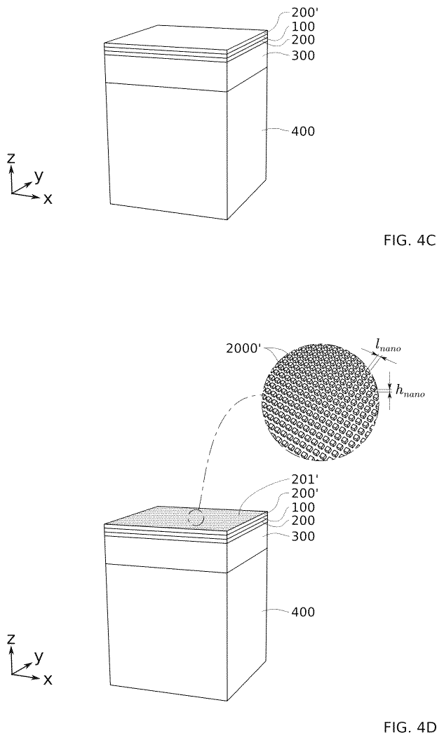

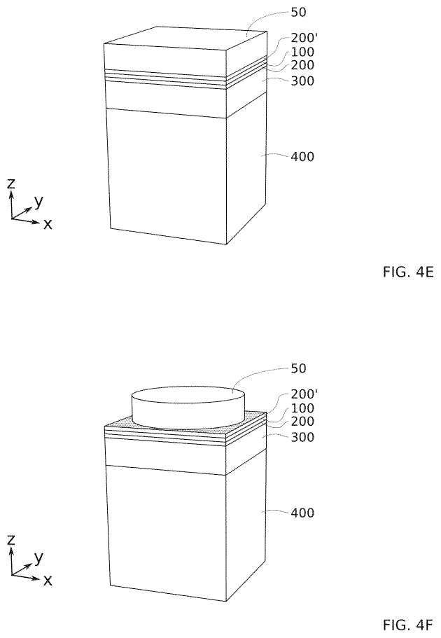

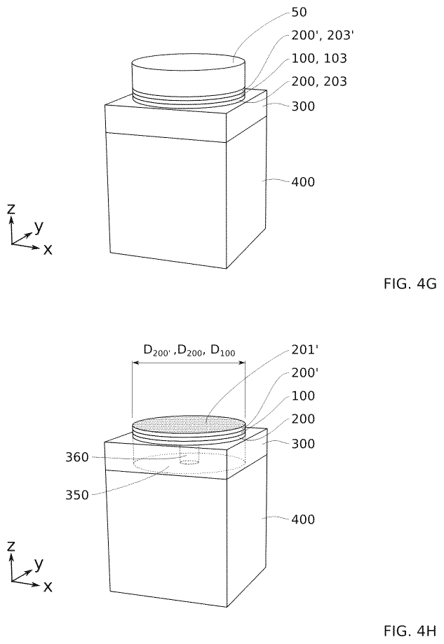

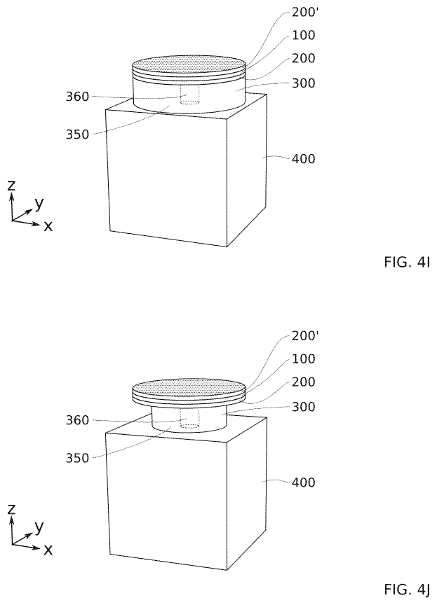

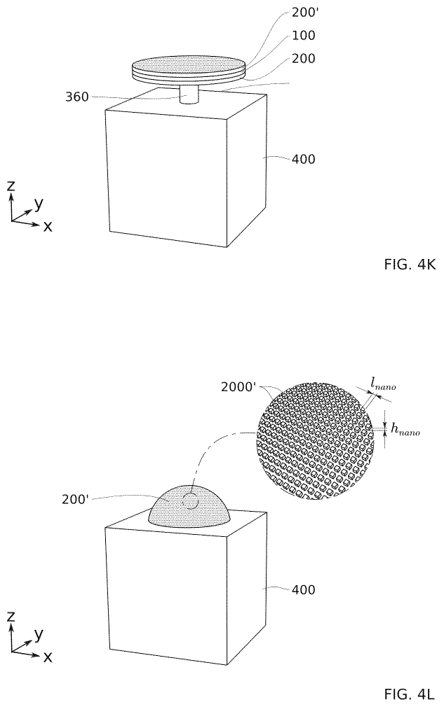

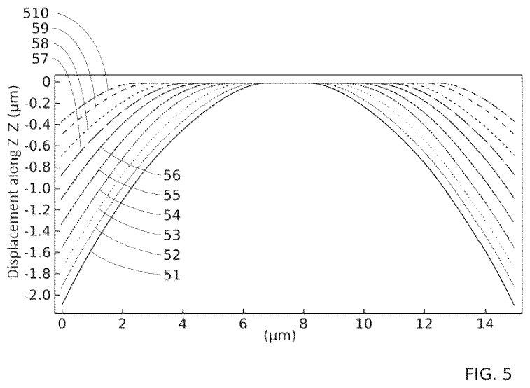

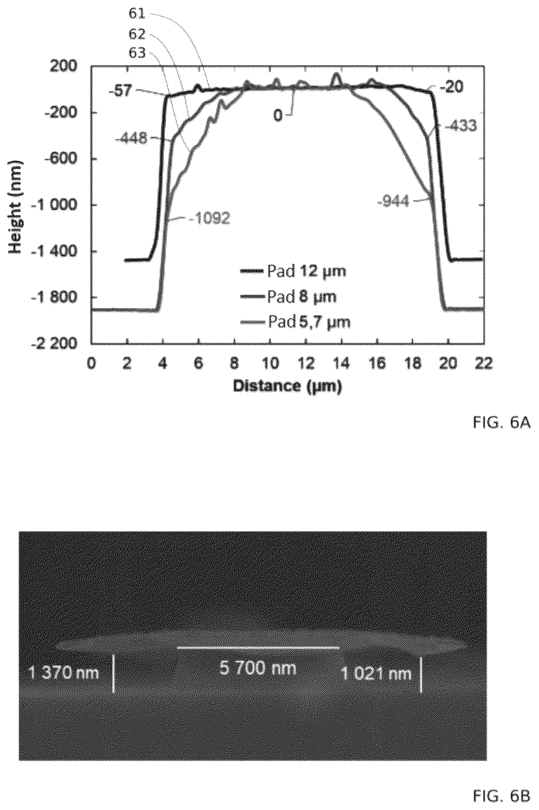

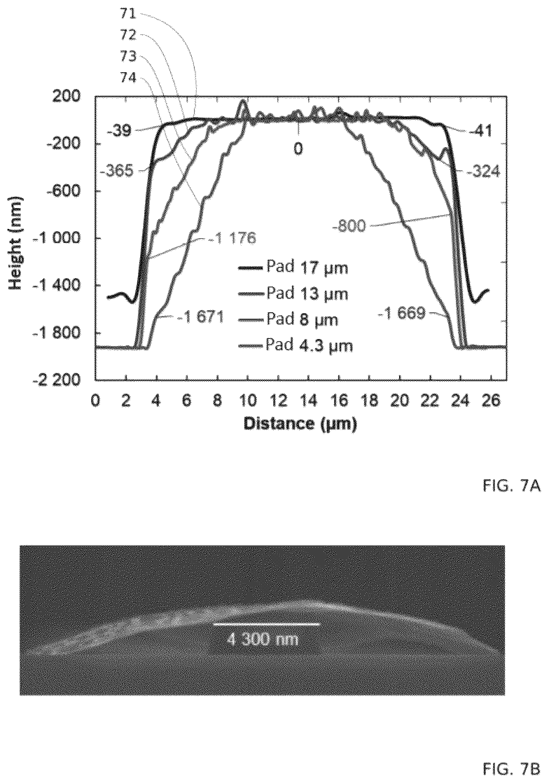

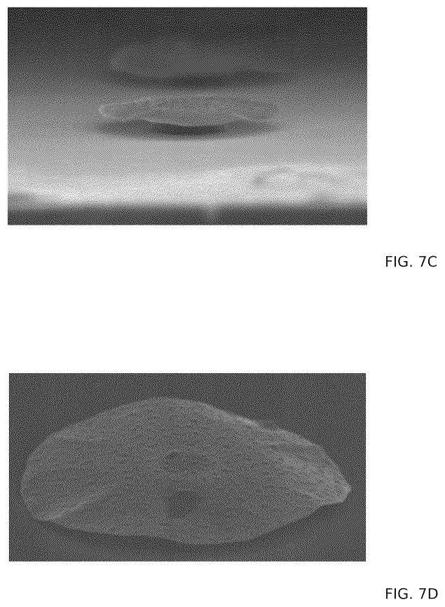

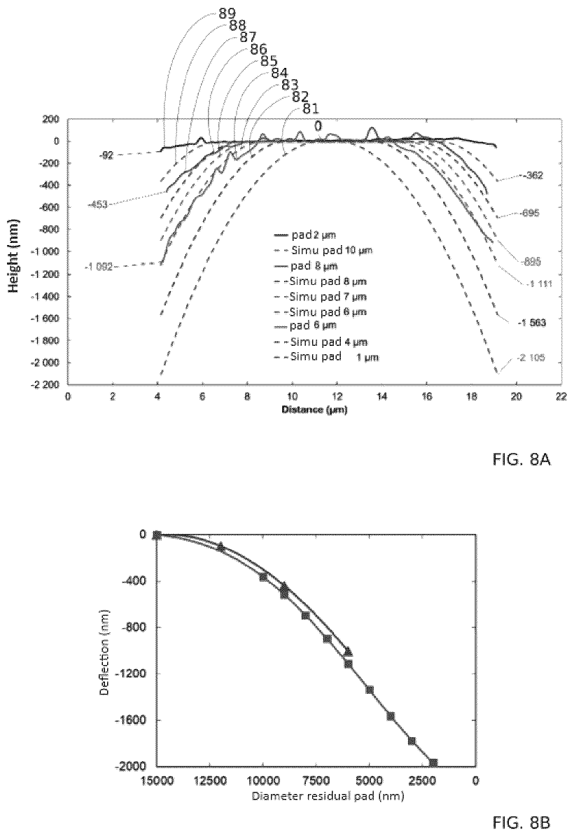

A reference frame, preferably orthonormal reference frame, comprising the axes X, Y, Z is represented in FIGS. 2A, 3A and 4A. This reference frame is applicable by extension to other figures.

In this patent application, thickness for a layer and height for a structure or a device will preferably be considered. The height is taken perpendicular to the horizontal plane XY. The thickness is taken in a direction normal to the main extension plane of the layer. Thus, a layer typically has a thickness along Z, when it extends mainly along the horizontal plane XY, and a projecting element, for example an insulation trench, has a height along Z. The relative terms on”, “under”, “underlying” refer preferentially to positions taken in the direction Z.

The terms “substantially”, “approximately”, “of the order of” mean “within 10%, preferably within 5%”.

A first embodiment of a three-dimensional structure will be described with reference to FIGS. 2A to 2M. For reasons of clarity, steps 2A to 2L illustrate obtaining a single three-dimensional structure. Naturally these steps allow to simultaneously obtain numerous three-dimensional structures from the same substrate as illustrated in the final FIG. 2M.

FIGS. 2A to 2G illustrate a sequence of steps allowing to obtain a stack 1, illustrated in FIG. 2G, which will be the subject of the method according to the invention.

FIG. 2A illustrates the provision of an initial stack comprising a support substrate 400, a sacrificial layer 300 and a layer of interest 200. Preferably, the layer of interest 200 is in contact with the sacrificial layer 300. However, it is conceivable that another layer is interposed in the vertical direction Z between the sacrificial layer 300 and the layer of interest 200.

A tensor layer 100 is then deposited on, preferably directly on, the layer of interest 100, as illustrated in FIG. 2B. The tensor layer 100 is typically deposited at low temperature, for example at a temperature below 250° C. for a deposition of TiN on a SOC (“System On Chip”).

FIGS. 2C to 2H illustrate a first structuring of the stack obtained in FIG. 2B, for example by lithography. This first structuring can be described as microstructuring. A masking layer 50 is first deposited on the tensor layer 100, then it is itself structured, for example by photolithography, as illustrated in FIG. 2D. The masking layer 50 is typically a photosensitive resin. The tensor layer 100 is then etched (FIG. 2E) then the layer of interest 200 (FIG. 2F) and possibly the sacrificial layer 300 through the masking layer 50. These etching steps are preferably carried out by an anisotropic etching method such as reactive ion etching or plasma etching. The masking layer 50 is then removed, for example by stripping (FIG. 2G).

The stack 1 illustrated in FIG. 2G and which is provided during the first step of the method according to the invention is thus obtained.

This stack 1 is described in more detail below.

The stack 1 comprises, stacked in the vertical direction Z, the support substrate 400, the sacrificial layer 300, the layer of interest 200 and the tensor layer 100. The layer of interest 200 and the tensor layer 100 each have a sidewall 203, 103 delimiting them in the horizontal plane XY.

Preferably, the tensor layer 100 completely covers the layer of interest 200. Advantageously, the layer of interest 200 and the tensor layer 100 have the same shape in projection in the horizontal plane XY. Preferably, the layer of interest 200 and the tensor layer 100 overlap in projection in the horizontal plane XY. In other words, the sidewall 103 of the tensor layer is preferably in the extension of the sidewall 203 of the layer of interest in the vertical direction Z.

According to a preferred embodiment, the sidewall 203 of the layer of interest 200 has a substantially circular shape in projection in the horizontal plane XY (FIG. 2N). In other words, in projection in the horizontal plane, the layer of interest 200 has the shape of a disc. The circular shape is particularly suitable for producing lenses or else microlenses from the layer of interest 200. It is understood, however, that these layers can be in any shape in projection in the horizontal plane XY, depending on the targeted applications.

In the same way, according to a preferred embodiment, the sidewall 103 of the tensor layer 100 has a substantially circular shape in projection in the horizontal plane XY. In other words, in projection in the horizontal plane, the tensor layer 100 has the shape of a disc.

When the sidewall 203 of the layer of interest 200 has, in projection in the horizontal plane XY, a substantially circular shape, a diameter of the layer of interest 200 denoted D₂₀₀ is defined. In the same way, when the sidewall 103 of the tensor layer 210 has, in projection in the horizontal plane XY, a substantially circular shape, a diameter of the tensor layer 100 denoted D₁₀₀ is defined.

The structuring of the layer of interest 200 to define its sidewall 203 is preferably described as microstructuring. Typically, D₂₀₀<1000 μm (10⁻⁶ meters) and preferably D₂₀₀<100 μm, preferably D₂₀₀<10 μm and preferably D₂₀₀<5 μm. Moreover, preferably D₂₀₀>20 nanometres.

The layer of interest 200 and the tensor layer 100 can also have, in projection in the horizontal plane XY, a substantially elliptical shape (FIG. 2O). A minor axis D_{200,y} of the layer of interest 200 and a major axis D_{200, x} of the layer of interest 200 are then defined for the layer of interest 200, and a minor axis D_{100, y} of the tensor layer 100 and a major axis D_{100, x} of the tensor layer 100 are then defined for the tensor layer 100. The minor and major axes can also be designated small and large diameters.

A second step of the method according to the invention illustrated in FIGS. 2H to 2J consists of a partial removal of the sacrificial layer 300 selectively to the layer of interest and to the tensor layer 100. More precisely, during this step, a removal portion 350 of the sacrificial layer 300 is removed while leaving in place a remaining portion 360 of this same layer 300. FIGS. 2H to 2J illustrate the progressive removal of the removal portion 250. The stack obtained after the complete removal of the removal portion 250 is illustrated in FIG. 2J.

The removal portion 350 and the remaining portion 360 are described in more detail below.

The removal portion 350 extends entirely in line with a lateral portion 250 of the layer of interest 200 in the vertical direction Z. The lateral portion 250 of the layer of interest 200 extends from the entire sidewall 203 of the layer of interest. Thus, in projection in the horizontal plane XY, when both the sidewall 203 of the layer of interest 200 and the sidewall of the remaining portion 363 are circular, and when the remaining portion 360 of the sacrificial layer is centred compared to the layer of interest 200, the lateral portion 250 has the shape of a circular crown. It is this example which is illustrated in FIGS. 2H to 2J.

The removal portion 350 also defines, at its internal sidewall 354, a closed contour in projection in the horizontal plane XY. This closed contour corresponds in particular to the projection in the horizontal plane XY of the sidewall 363 of the remaining portion 360. Indeed, the internal sidewall 354 of the removal portion 350 and the sidewall 363 of the remaining portion 360 are merged. Advantageously, this closed contour is circular in shape. When this is the case, a diameter of the remaining portion 360 denoted D₃₆₀ is defined.

The remaining portion 360 of the sacrificial layer 300 is located in line with a portion called central portion 260 of the layer of interest 200.

A lateral portion 150 and a central portion 160 of the tensor layer 100, located respectively in line with the lateral portion 250 of the layer of interest 200 and in line with the central portion 260 of the layer of interest 200 are also defined.

The remaining portion 360 of the sacrificial layer forms in this example a pad 360.

According to an advantageous embodiment of the invention, both the layer of interest 200, the tensor layer 100 and the pad 360 have a circular shape in projection in the horizontal plane XY and are concentric in this same plane. The assembly consisting of the pad 360, the layer of interest 200 and the tensor layer then admits a symmetry of revolution around an axis 1000 parallel to the vertical direction Z.

The removal of the removal portion 350 as well as its effects on the stack 1 will now be described.

The removal of the removal portion 350 is carried out by etching, typically etching with hydrofluoric acid (HF) in the vapour phase.

This removal allows a partial mechanical release of the layer of interest 200 and the tensor layer 100. This release is particularly effective at the lateral portion 250 of the layer of interest 200 and the lateral portion 150 of the tensor layer 100. Indeed, during the step of supplying the stack 1, and generally before the removal step, the layer of interest 200 and the tensor layer 100 rest entirely on the sacrificial layer 300 and are therefore maintained by it. Once the removal portion 350 is removed, the layer of interest 200 and the tensor layer 100 are suspended on the pad 360. They rest on the pad 360 at the central portion 260 of the layer of interest 200 and, indirectly, at the central portion 360 of the tensor layer 100. The pad 360 is thus the only element connecting the support substrate 400 and the layer of interest 200.

The tensor layer 100 and the layer of interest 200 each have, before the mechanical release step, a residual stress denoted respectively σ₁₀₀ and σ₂₀₀ These residual stresses σ₁₀₀ and σ₂₀₀ are generated by the deposition conditions of the layers that they characterise. They can be either in tension or in compression. In the particular case of an SOI (“Silicon On Insulator”) substrate whose upper layer of silicon can play the role of layer of interest, the manufacture of the substrate generally generates a residual stress in tension in silicon, typically from a few MPa to a few GPa.

Due to the removal of the removal portion 350, the residual stresses σ₁₀₀ and σ₂₀₀ cause deformations of the layer of interest 200 and the tensor layer 100, in particular at their lateral portions 250, 150, In this sense, FIG. 2J illustrates a theoretical step wherein the removal portion 350 would be removed and the layer of interest 200 and tensor layer 100 would have the same shape as before this removal. Such a stack is in reality unstable: the deformation of the layer of interest 200 and the tensor layer 100 actually takes place as soon as the removal is carried out and even during the removal. FIG. 2K illustrates the stack having this deformation.

The residual stress σ₂₀₀ of the layer of interest 200 is generally fixed by the different steps that it undergoes upstream of the method according to the invention. Thus, it is the residual stress σ₁₀₀ of the tensor layer 100 which is configured to allow the desired deformation of the layer of interest 200. The sign of the sum of the residual stress σ₁₀₀ of the tensor layer 100 and the residual stress σ₂₀₀ of the layer of interest indicates the direction of the deformation of the layer of interest 200 caused by the tensor layer 100 (approaching or moving away from the layer of interest 200 relative to the support substrate 400). The amplitude of deformation of the layer of interest 200 is also determined by the configuration of the residual stress σ₁₀₀ the tensor layer 100.

The residual stress σ₁₀₀ of the tensor layer 100 is chosen according to the desired bending taking into account different parameters and in particular the residual stress σ₂₀₀ of the layer of interest 200 and the thickness e₂₀₀ according to the vertical direction Z of the layer of interest 200.

The thickness e₁₀₀ in the vertical direction Z of the tensor layer 100 is also a parameter having a direct impact on the residual stress σ₁₀₀. The greater the thickness e₁₀₀ the lower the residual stress σ₁₀₀. When the tensor layer 100 is based on TiN, the thickness e₁₀₀ is typically comprised between a few nanometres, for example 2 nanometres, and around 100 nanometres. The thickness e₁₀₀ is generally chosen according to the materials used so as to obtain the desired stress level in the tensor layer 100.

The various parameters, including in particular the thickness e₁₀₀ of the tensor layer and its residual stress σ₁₀₀, can be chosen so as to cause tension or compression of the layer of interest 200, and thus cause a separation or an approximation of the latter to the support substrate 400. The method according to the invention can thus allow to deform the layer of interest 200 in both directions of the vertical direction Z. Titanium nitride (TiN) and silicon nitride (SiN) and more generally nitrides have the advantage of being able to be tensioned or compressed depending on their deposition conditions. Therefore, they constitute very interesting materials for making the tensor layer 100. TiN is particularly compressive over ranges from a hundred MPa to a few GPa and for a thickness of a few nanometres to a hundred nanometres.

By using specific deposition conditions and by correctly sizing the different layers, it is therefore possible to induce the desired deformation (direction and amplitude) of the layer of interest 200. The person skilled in the art is perfectly able to adapt these parameters to obtain the desired deformation.

Advantageously, the method allows, during the removal of the removal portion 350, to cause the deformation of the entire layer of interest 200 in a single direction of bending. In particular, the residual stress σ₁₀₀ of the tensor layer 100 and possibly its thickness e₁₀₀ is configured/are configured so that the entire layer of interest 200 follows the same movement: that is to say an approximation with respect to the support substrate 400, that is to say a separation from the support substrate 400. These two alternatives can be designated “downward bending” and “upward bending”. Thus, once the removal has been carried out, the layer of interest 200 has a homogeneous shape, preferably having a symmetry of revolution around an axis parallel to the vertical direction Z. For example, in the case of a circular layer of interest 200, once the removal portion 350 is removed, the layer of interest 200 has a shape approximating a spherical cap, that is to say a portion of a sphere delimited by a plane. It is understood that slight deviations from a perfect shape may exist, depending on manufacturing hazards and/or the structural homogeneity of the different layers, and in particular of the layer of interest. These deviations can also correspond to the nanostructuring of the layer of interest 200 described above.

It should be noted that the residual stresses σ₁₀₀, σ₂₀₀ can be adapted, at least locally, in order to attenuate or exacerbate the bending caused by the removal step. For this purpose, it is possible to implement thermal annealing or ion implantation in these layers before the removal step. Thermal annealing can optionally take place during the removal step, and ion implantation can also be implemented after the removal step.

Thermal annealing causes a relaxation of the mechanical stresses of the layer. The residual stress will mainly depend on the difference in thermal expansion coefficient between the substrate and the annealed layer, or between the annealed layer and the underlying layer. It is therefore possible, for example, by relaxing the mechanical stresses before or during the method according to the invention, to make a layer initially in compressive stress, in tensile stress.

Ion implantation can allow to modify the constraints on certain localized areas of the layer of interest 200 and/or the tensor layer 100. This allows very precise control of the curvature during the removal step.

Thus, the step of partial removal of the sacrificial layer 300, or release step, allows bending of the layer of interest 200, this bending being able to be perfectly controlled, even locally.

FIG. 2P is a sectional view of the stack showing both the layer of interest 200 and the tensor layer 100 before (dotted lines) and after (solid lines) deformation. This figure shows how the deformation of the layer of interest 200 can be quantified.

In the advantageous case where the layer of interest 200 and the pad 360 both have a circular shape in projection in the horizontal plane XY and are concentric in this same plane, as is the case in FIG. 2P, the deformation can be measured according to the vertical direction Z, between:
a. an upper plane 1001 wherein the lower face 252 of the central portion 250 of the layer of interest 200 is included, and
b. a lower plane 1002, parallel to the upper plane 1001 and passing through the lower edge 204 of the layer of interest 200, generally constituting the area of the layer of interest 200 having undergone the greatest vertical displacement. The lower edge 204 of the layer of interest 200 is defined by the intersection of the sidewall 203 of the layer of interest 200 and its lower face 202.

The distance in the vertical direction Z between these two planes 1001, 1002 is called the arrow of the layer of interest 200 and is denoted f₂₀₀.
When the layer of interest 200 and the pad 360 are in contact as illustrated in FIG. 2P, the upper face 361 of the pad 360 is also included in the upper plane 1001.

The lower face 202 of the layer of interest 200 is also typically included in the upper plane 1001 before deformation.

In general, even when the stack does not admit a symmetry of revolution (for example due to manufacturing hazards), the deformation of the layer of interest 200 can be characterised at any point of the edge 204 of the layer of interest 200 by a local arrow. The arrow f₂₀₀ of the layer of interest 200 will typically be assimilated to the deformation measured at the point of the edge 204 having the highest local arrow.

Preferably, after removing the removal portion 350, the arrow f₂₀₀ of the layer of interest 200 is greater than 100 nm, preferably greater than 200 nm or even greater than nm.

In the case where the layer of interest 200 is deformed so as to be brought closer to the support substrate 400, it can be sought to ensure that there is at least partial contact between the layer of interest 200 and the support substrate 400, at the upper face 401 of the latter. Advantageously, the different parameters of the method are configured so that this contact induces at least partial bonding of the layer of interest 200 and the support substrate 400. According to a particular embodiment, the contact alone ensures bonding. Such bonding is particularly possible when the support substrate 400 and the layer of interest 200 are based on the same material, for example silicon. When the layer of interest is deformed until it is bonded to the support substrate 400, the height hₗₑₙₛ of the structure obtained, typically a lens, is equal to the sum of the height h₃₆₀ of the pad 360 and the thickness e₂₀₀ of the layer of interest 200 (see FIGS. 2J and 2L). The thickness e₂₀₀ of the layer of interest 200 being generally small relative to the height h₃₆₀ of the pad 360, in this case the approximation hₗₑₙₛ≈h₃₆₀ no is made.

As illustrated by the passage from FIG. 2K to FIG. 2L, the removal of the tensor layer 100 is advantageously provided after the step of partial removal of the sacrificial layer 300. This allows to update the layer of interest 200. In the case of a layer of interest made of Si and a tensor layer made of TiN, a wet etching called SC1 (cleaning bath NH₄OH/H₂O₂/H₂O, with a ratio generally ranging from 1:2:2 to 1:1:5) allows total and selective removal of TiN relative to Si.

This removal is facilitated when at least partial bonding of the layer of interest 200 with the upper face 401 of the support substrate 400 has taken place. Indeed, thanks to bonding, the layer of interest 200 remains in place and retains the shape given thereto by the tensor layer 100. When it is not bonded to the support substrate 400, the layer of interest risks undergoing a new deformation during the removal of the tensor layer 100. This new deformation would be oriented in the direction opposite to the direction of the deformation taking place during the step of partial removal of the sacrificial layer 300. This embodiment thus further improves control of the final shape given to the three-dimensional structure. Bonding the layer of interest to the support substrate 400 can prevent this second deformation. It is understood, however, that in the event of no bonding between the layer of interest 200 and the support substrate 400, this second deformation can also be anticipated and taken into account to obtain the desired final deformation.

Although FIGS. 2A to 2L illustrate the implementation of the method for a single three-dimensional structure, it is understood that the method according to the invention can be implemented for a plurality of three-dimensional structures sharing the same support substrate 400. FIG. 2M illustrates the result that would then be obtained. The references 200a, 200b, 200c designate the different layers of interest of each of the structures obtained visible from this view. The steps described with reference to FIGS. 2A to 2L can be carried out simultaneously for a plurality or even all the structures. In this embodiment, before removal of the removal portion associated with each layer of interest 200a, 200b, 2000, the latter have a face disposed in the same plane, here a horizontal plane. Typically, the upper faces of the layers of interest 200a, 200b, 2000 can form distinct discs disposed in the same plane.

The following paragraphs aim at proposing several combinations of materials that can be used for each of the layers of the stack 1. Naturally, these examples are not limiting and the method described can be implemented with numerous other materials.

### Example 1

a. Support substrate: Si or glass
b. Sacrificial layer: SiO₂
c. Layer of interest: Si or SiGe
d. Tensor layer: TiN or AlN

### Example 2

a. Support substrate: Si or glass
b. Sacrificial layer: SiARC
c. Layer of interest: Si or SiGe
d. Tensor layer: TiN or AlN

### Example 3

a. Support substrate: Si or glass
b. Sacrificial layer: SiON
c. Layer of interest: Si or SiGe
d. Tensor layer: TIN or AlN

### Example 4

a. Support substrate: Si or glass
b. Sacrificial layer: SiN
c. Layer of interest: Si, for example amorphous silicon
d. Tensor layer: TiN or AlN

### Example 5

a. Support substrate: Si or glass
b. Sacrificial layer: SiN
c. Layer of interest: SiGe
d. Tensor layer: TIN or AlN

The method according to the invention can be the subject of digital simulations carried out by the finite element method (commonly referred to by the acronym FEM). These simulations aim at predicting the different dimensional and experimental parameters necessary to obtain a structure with the desired shape and dimensions. Typically, it is sought to know the lateral dimensions of the pad 360— and therefore the etching time of the sacrificial layer 300— required to obtain the desired bending, for example a bending leading to the bonding of the layer of interest 200 to the support substrate 400.

The simulations, the results of which are presented in FIG. 5, relate to the particular and preferred case of circular structures. Therefore, of special interest is the diameter of the layer of interest 200 and the tensor layer 100 and the diameter of the pad 360. The objective here is to determine the etching time required so that the diameter of the pad 360 is such that the bending of the layer of interest 200 leads to bonding the latter to the support substrate 400, according to the height of the pad 360. The other parameters (materials, thicknesses of the layer of interest 200 and of the tensor layer 100 . . . ) are fixed. It should be noted that in this non-limiting example, the objective being to obtain the bonding of the layer of interest 200 to the support substrate 400, the height h₃₆₀ of the pad 360 corresponds to the height hₗₑₙₛ of the lens obtained at the end of the method.

The structure incremented in the software comprises an SOI substrate comprising a buried oxide (BOX) acting as a sacrificial layer and a silicon layer acting as the layer of interest. The buried oxide, based on SiO₂, has a thickness of 2 μm in the vertical direction Z while the silicon layer has a thickness of 50 nm. A layer of titanium nitride (TiN) acts as a tensor layer and has a thickness of 30 nm.

In projection in the horizontal plane XY, the layer of interest and the tensor layer have a diameter of 15 μm. These layers rest on a SiO₂ pad having a height of 2 μm and a diameter varying from 1 to 10 μm. The ratio between the height and the diameter of the lens obtained at the end of the method is therefore equal to 7.5.

The different curves of the graph shown in FIG. 5 correspond to the same simulation, carried out for different values of diameter D₃₆₀ of the pad 360 of SiO₂ (curve 51: D₃₆₀=1 μm, curve 52: D₃₆₀=2 μm, curve 53: D₃₆₀3 μm, curve 54: D₃₆₀=4 μm, curve 55: D₃₆₀=5 μm, curve 56: D₃₆₀=6 μm, curve 57: D₃₆₀=7 μm, curve 58: D₃₆₀=8 μm, curve 59: D₃₆₀=9 μm, curve 510: D₃₆₀=10 μm). Thus, they illustrate the deflection of the layer of interest 200 (silicon layer) according to the diameter of the pad 360.

It is observed in particular that these results predict a homogeneous bending of 2 μm for a SiO₂ pad having a diameter of 2 μm. However, the height h₃₆₀ of the SiO₂ pad is 2 μm (thickness of the BOX). Therefore, we have h₃₆₀=hₗₑₙₛ for d₃₆₀=2 μm. This simulation therefore allows to predict that it is necessary to give the SiC₂ pad a diameter of 2 μm to obtain bonding of the layer of interest 200 with the support substrate 400. The conditions for etching the sacrificial layer (BOX of the SOI) arise directly from this.

The method according to the invention therefore has the advantage of having results that can be easily anticipated. Its implementation is made easier and the structures obtained correspond perfectly to the set specifications.

Experimental examples will now be presented with reference to FIGS. 6A to 70.

A first example is made with the following stack:
a. Sacrificial layer made of SiO₂ having a thickness of 2 μm,
b. Layer of interest made of Si having a thickness of 20 nm, a diameter of 15 μm and a residual stress of +0.133 MPa,
c. Tensor layer made of TiN with a thickness of 30 nm, a diameter of 15 μm and a residual stress of −2.02 GPa.

The lithography mask used for microstructuring allows to produce plots of 5, 10, 15 and 20 μm from the sacrificial layer. Once the transfer has been carried out in TIN then in silicon by dry etching, following the method described above with reference to FIGS. 2C to 2G, vapour etching with HF is carried out in several steps. The theoretical etching speed used is 25 nm/min. After each etching step, the stressed suspended discs are measured using an atomic force microscope (or AFM, for “Atomic Force Microscopy”) (FIG. 6A), then images taken by scanning electron microscopy (SEM) in cross section are carried out after the last etching step (FIG. 6B).

A first etching step leads to a first release characterised by a residual SiO₂ pad having a diameter of 12 μm. This first release causes a deflection of around forty nanometres (curve 61). A second etching step allows greater release of the layer of interest and the tensor layer. It is characterised by a residual SiO₂ pad with a diameter of 8 μm. It produces a deflection of approximately 440 nm (curve 62). Finally, a third and final etching to obtain a residual SiO₂ pad with a diameter of 5.7 μm generates a deflection of 1 000 nm (curve 63).

The cross-sectional SEM image (FIG. 6B) confirms that at the end of the method, the SiO₂ pad 360 has a diameter of 5.7 μm.

A similar study is carried out with the same experimental parameters except for the diameter of the layer of interest and the tensor layer, this time set at 20 μm. The results obtained are presented in FIG. 7A (AFM analysis) and FIGS. 7B to 7D (SEM images).

The first three etching steps give results very close to those obtained for a 15 μm disc. Indeed, the successive releases initially produce an average deflection of around forty nanometres (curve 71), then around 350 nm (curve 72) and finally a maximum of 1 176 nm (curve 73). The fourth and final release by etching gives rise to residual pads of 4.3 μm (curve 74). The AFM profile shows a deflection of approximately 1 670 nm. However, on the SEM image reproduced in FIG. 7B, the microdisc is in contact with the substrate, which means that deflections of 2 000 nm (height of the SiC₂ pad) are reached in places. These results show that the formation of 3D structures with a height of 2 μm is achievable by controlled bending of microdiscs. Furthermore, the bent microdiscs are resilient despite the small thicknesses of the silicon layers (layer of interest) and titanium nitride (tensor layer).

FIGS. 7C and 7D are SEM images taken from viewing angles different from that of FIG. 7B which constituted a sectional view of the structure. These images show that certain areas of the layer of interest have a greater deflection than others. Indeed, certain areas of the microdiscs have greater bending. In the case studied here, this inhomogeneous deformation can be caused by the layer of interest, made up of silicon. Indeed, the crystallinity of silicon generates different physical properties depending on the crystal directions, leading for example to variations in the Young's modulus from 130 to 180 GPa. These differences in deflection may have no impact on the performance of the structure, and it is therefore possible to ignore them. If, on the contrary, it is sought to obtain a homogeneous deflection, preferably a layer of interest 200 based on amorphous materials will be used. The use of this type of materials allows to overcome variations in intrinsic physical properties related to crystal directions. The deformation is therefore homogeneous over the entire structure.

The experimental results for the 15 μm microdiscs were superimposed on the results of the simulations carried out by the finite element method.

FIG. 8A shows the experimental results in solid lines and those of the numerical simulations in dotted lines, for different diameters of residual pads (curve 31: 1 μm, curve 82: 4 μm, curves 83 and 34: 6 μm, curve 85: 7 μm, curves 86 and 37: 8 μm, curve 88: 10 μm, curve 39:12 μm). For residual pads of 6 and 3 μm, the deflection curves obtained by simulation overlap perfectly with the experimental ones. Thus, for a 6 μm pad, the maximum experimental deflection is 1092 nm compared to 1111 nm in the simulation.

FIG. 8B shows the maximum deflection obtained as a function of the diameter of the residual pad for the results of the simulations (curve with square points) and experimental results (curve with triangular points). In addition to the proximity of the results between the two, it should be noted that the maximum deflections obtained by simulation form an S-shaped curve as a function of the diameter of the pad. This form agrees with the first experimental results.

The results obtained agree with the simulations of manufacturing 3D microstructures by controlled bending of microstructures. This shows that the method described above allows to obtain three-dimensional structures whose shapes are perfectly predictable. Furthermore, the person skilled in the art can easily establish a chart of 3D microstructures achievable by controlled bending.

According to an advantageous embodiment of the invention, the method comprises a step of structuring the layer of interest 200 or a secondary layer of interest 200′.

This structuring can for example be described as nanostructuring. The patterns produced by this structuring have dimensions greater than those of the layer of interest 200. Typically the nanostructuring forms patterns having critical dimensions less than one micrometre and preferably less than 500 nanometres, or even less than 100 nanometres, or even less than 20 nanometres.

Such nanostructuring can confer very advantageous properties to the structure formed. In the case of microlenses, nanostructuring can for example give them anti-reflective properties.

This application is inspired by the eyes of moths, the surface of which can be compared to an array of microlenses, each having an anti-reflective nanometric structure. On the one hand, the microlens network allows light to be focused on photoreceptors, thus improving the insect's field of vision. This microlens array is obtained by bending deformation of the layer of interest according to the method described above. On the other hand, the nanometric array increases the amount of light captured by the eye by reducing light reflections, regardless of the incident angle of the light. This nanometric array is obtained by texturing the layer of interest. Furthermore, the combination of these two structures—micrometric and nanometric structures—provides other functionalities in the eyes of moths, such as super-hydrophobicity and an anti-fogging effect.

This multiple structuring is commonly called hierarchical or multi-scale structure. The creation of such structures today faces strong integration constraints, the addition of a nanometric structure on a non-planar micrometric form being not trivial.

The method according to this embodiment constitutes a solution first going through nanometric structuring, then microstructuring. Thanks to this chronology, nanostructuring is facilitated since it is carried out on a flat surface, before the bending of the layer of interest. This has the advantage of offering flexibility with regard to the imaginable nanostructures and nanostructuring methods that can be implemented. In particular, it is possible to use nanostructuring techniques as varied as optical lithography, the self-assembly of block copolymers or else nanoimprinting. The technique used, for example the type of optical lithography, can be chosen according to the resolution desired for the nanostructuring.

A first example of the embodiment with nanostructuring is illustrated in FIGS. 3A to 3O.

FIG. 3A, like FIG. 2A, illustrates the provision of an initial stack comprising the support substrate 400, the sacrificial layer 300 and the layer of interest 200. FIG. 3B illustrates the nanostructuring of the layer of interest 200 from its upper face 201. This step of nanostructuring the upper surface 201 allows to form in the layer of interest 200 nanostructures 2000 having a height hₙₐₙₒ in the vertical direction Z and a characteristic dimension Iₙₐₙₒ in the horizontal plane XY. If the nanostructures 2000 have the shape of a square in projection in the plane XY, Iₙₐₙₒ will correspond for example to the sidewall of this square. Typically Iₙₐₙₒ<100 nanometres.

A planarisation layer 500 is then deposited on the layer of interest 200 (FIG. 3C) in order to allow the deposition of the tensor layer (FIG. 3D) to take place on a flat surface.

The steps illustrated by FIGS. 3E to 3L are similar to the steps described previously with reference to FIGS. 2C to 2J. The only difference lies in that the etching of the stack through the masking layer 50 also comprises the etching of the planarisation layer 500. During these steps, the layer of interest 200 is microstructured, preferably so as to give it a circular shape in the horizontal plane XY. It then has a diameter D₂₀₀ in the horizontal plane XY. Typically an aspect ratio comprised between 40 and 1000 between Iₙₐₙₒ and D₂₀₀ is obtained According to one example, the patterns produced by nano structuring are distributed over the entire surface of the layer of interest 200. Alternatively, they can be distributed over only one area of the layer of interest 200 while leaving another area of the layer of interest 200 free. According to one example, these patterns are distributed periodically. They can also be distributed non-periodically. This allows, for example, to associate the patterns of the nanostructuring with certain angles of incidence only of light rays reaching the lens covered with these nanostructurings.

Following the removal of the removal portion 350 of the sacrificial layer, the layer of interest and the planarisation layer 50 undergo bending due to the residual stresses residing in the tensor layer 100 (passage from FIG. 3L to FIG. 3M).

Preferably, the tensor layer 100 (FIG. 3M) is removed then the planarisation layer (FIG. 3N) is removed in order to update the layer of interest 200 having the nanostructuring carried out previously (FIG. 3O).

A second example of the embodiment with nanostructuring is illustrated in FIGS. 4A to 4L.

FIG. 4A, like FIG. 2A and FIG. 3A, illustrates the provision of an initial stack comprising the support substrate 400, the sacrificial layer 300 and the layer of interest 200. As illustrated in FIG. 4B, the tensor layer 100 is then deposited on the layer of interest 200.

A secondary layer of interest 200′ is then deposited on the tensor layer 100 (FIG. 4C). This time it is the upper surface 201′ of the secondary layer of interest 200′ which is nanostructured (FIG. 4D), so as to form nanostructures 2000′. The features described in the context of the previous example regarding the nanostructuring of the layer of interest apply mutatis mutandis to the nanostructuring of the secondary layer of interest 200′.

The steps illustrated by FIGS. 4E to 4K are similar to the steps described previously with reference to FIGS. 2C to 2J. The only difference lies in that the etching of the stack through the masking layer 50 also comprises the etching of the secondary layer of interest. During these steps, the secondary layer of interest 200′ is microstructured, preferably so as to give it a circular shape in the horizontal plane XY. Then it has a diameter D_{200′} in the horizontal plane XY. Typically an aspect ratio comprised between 40 and 1000 between Iₙₐₙₒ and D_{200′} is obtained.

Following the removal of the removal portion 350 of the sacrificial layer, the layer of interest 200 and the secondary layer of interest 200′ undergo bending due to the residual stresses residing in the tensor layer 100 (passage from FIG. 4K to FIG. 4L).

In this example, the nanostructured surface (upper surface 201′ of the secondary layer of interest 200′) is located above in the vertical direction of the tensor layer 100. In order to be able to use this surface for various applications, therefore the tensor layer is not removed.

The nanostructured 3D structure thus obtained finds a particularly advantageous application in nanoimprinting. It can indeed serve as a master mould in such a method.

Through the different embodiments described below, it clearly appears that the invention offers an efficient and simple-to-implement solution for manufacturing 3D structures, particularly microlenses, possibly having a nanometric level of structuring.

It is understood that the principle of double structuring applied to the method according to the invention can be implemented on a larger scale. For example, it is possible to carry out a first structuring to form an overall device (typically a lens) of several hundred micrometres using the controlled bending technique described previously. An array of microlenses on the surface of the lens can be produced upstream, by a second structuring, according to the same methods as those described previously for obtaining a nanostructuring on the surface of a microlens. In this case, the characteristic dimensions of the second structure correspond to those of a microstructure as presented above.

The invention is not limited to the embodiments previously described and extends to all the embodiments covered by the invention.

1. A method for manufacturing a three-dimensional structure, the method comprising:
supplying a stack comprising, stacked in a direction called vertical direction, at least:
a support substrate,
a sacrificial layer,
a layer of interest delimited in all directions of a horizontal plane perpendicular to the vertical direction, by a sidewall,
a tensor layer delimited in all directions of the horizontal plane by a sidewall, the tensor layer having a residual stress σ₁₀₀, and
removing a removal portion of the sacrificial layer, selectively from the layer of interest and the tensor layer, the removal portion forming a closed contour in projection in the horizontal plane, the removal portion being entirely located in line with a lateral portion of the layer of interest extending from the entire sidewall of the layer of interest, the removal of the removal portion being carried out so as to retain a remaining portion of the sacrificial layer, located in line with the layer of interest and the sacrificial layer,
the residual stress σ₁₀₀ of the tensor layer being configured to cause bending of the entire layer of interest in a single direction of bending during the step of removing the removal portion.

2. The method according to claim 1, wherein the sidewall of the layer of interest and the sidewall of the tensor layer each have a substantially elliptical or substantially circular shape in projection in the horizontal plane.

3. The method according to claim 1, wherein the remaining portion has a sidewall having a substantially elliptical or substantially circular shape in projection in the horizontal plane.

4. The method according to claim 2, wherein the sidewall of the layer of interest, the sidewall of the tensor layer and the sidewall of the remaining portion each have a substantially circular shape in projection in the horizontal plane, wherein the layer of interest has a diameter D₂₀₀ in the horizontal plane and the remaining portion has a diameter D₃₆₀ in the horizontal plane, and wherein, after removing the removal portion, the layer of interest has an arrow f₂₀₀, with f₂₀₀≥0.05*D₂₀₀−D₃₆₀).

5. The method according to claim 4, wherein the layer of interest has a diameter D₂₀₀ in the horizontal plane and the remaining portion has a diameter D₃₆₀ in the horizontal plane, and wherein, after removing the removal portion, the ratio D₂₀₀/D₃₆₀ is greater than 2.

6. The method according to claim 3, wherein the sidewall of the layer of interest, the sidewall of the tensor layer and the sidewall of the remaining portion each have a substantially elliptical shape in projection in the horizontal plane, wherein the layer of interest has a minor axis D_{200,y} in the horizontal plane and the remaining portion has a minor axis D_{360,y} in the horizontal plane, and wherein, after removing the removal portion, the layer of interest has, in section along a plane perpendicular to the horizontal plane and containing the minor axis of the layer of interest, an arrow f₂₀₀, with f₂₀₀≥0.05*(D_{200,y}−D_{360,y}.

7. The method according to claim 1, wherein, at least during the removal step, the sidewall of the tensor layer is in the extension of the sidewall of the layer of interest in the vertical direction.

8. The method according to claim 1, further comprising after the step of removing the removal portion, removing the tensor layer.

9. The method according to claim 1, wherein the bending of the layer of interest brings the sidewall closer to the substrate.

10. The method according to claim 9, wherein the bending of the layer of interest causes contact of the layer of interest with the support substrate.

11. The method according to claim 10, further comprising bonding at least part of the layer of interest with the support substrate.

12. The method according to claim 1, wherein the bending of the layer of interest moves the sidewall away from the substrate.

13. The method according to claim 1, wherein |σ₁₀₀|>500 MPa.

14. The method according to claim 1, wherein, before the removal step, the layer of interest has a residual stress σ₂₀₀ with |σ₂₀₀|≤100 MPa.

15. The method according to claim 1, wherein the layer of interest, after the step of removing the removal portion of the sacrificial layer, forms a lens.

16. The method according to claim 1, wherein the stack comprises a plurality of layers of interest distinct from each other and contained in a same plane parallel to the horizontal plane before the step of removing the removal portion of the sacrificial layer.

17. The method according to claim 16, wherein each layer of interest forms a lens.

18. The method according to claim 1, further comprising, prior to the step of removing the removal portion of the sacrificial layer, a step of structuring the at least one layer of interest.

19. The method according to claim 1, wherein the stack further comprises a secondary layer of interest above the tensor layer, wherein the removal of the removal portion is also carried out selectively at the secondary layer of interest, and
the method further comprises, prior to the step of removing the removal portion, a step of structuring the secondary layer of interest.

20. The method according to claim 1, wherein the structuring step further comprises the implementation of at least one technique among optical lithography, self-assembly of block copolymers, or nanoimprinting.
